(19) United States
(12) Patent Application Publication
(10) Pub. No.: US 2006/0240679 A1
(43) Pub. Date: Oct. 26, 2006

(54) Method of manufacturing semiconductor device having reaction barrier layer

(76) Inventors: Seung-Hwan Lee, Seoul (KR); Kyoung-Ryul Yoon, Goyang-si (KR); Han-Mei Choi, Seoul (KR); Ki-Yeon Park, Yongin-si (KR); Young-Sun Kim, Suwon-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/403,935

(22) Filed: Apr. 14, 2006

(30) Foreign Application Priority Data
Apr. 21, 2005 (KR) 2005-0032945

(51) Int. Cl. H01L 21/31; H01L 21/469

(52) U.S. Cl. 438/785

(57) ABSTRACT

A method of manufacturing a semiconductor device comprises forming a lower electrode on a substrate using a titanium chloride pulsed deposition (TPD) process, forming a high-k dielectric layer on the lower electrode, and forming an upper electrode on the dielectric layer using a TPD process. The method further comprises forming a reaction barrier layer between the upper or lower electrode and the dielectric layer using an atomic layer deposition (ALD) process. The upper electrode is preferably formed with a processing temperature between 350 and 500° C., and the dielectric layer preferably comprises zirconium oxide.

### BACKGROUND OF THE INVENTION

1. Field of the Invention

Embodiments of the present invention relate generally to methods of manufacturing semiconductor devices. More particularly, embodiments of the invention relate to methods of manufacturing semiconductor devices having a high-k dielectric layer.

A claim of priority is made to Korean Patent Application No. 2005-32945 filed on Apr. 21, 2005, the disclosure of which is hereby incorporated by reference in its entirety.

2. Description of Related Art

The manufacture of modern semiconductor devices generally involves a large number of processing steps performed on a substrate such as a semiconductor wafer. The processing steps may include, for example, layer formation processes for depositing layers on the substrate, oxidation processes for forming oxide layers on the substrate, photolithography processes for forming patterns in various layers formed on the substrate, and planarization processes for planarizing layers formed on the substrate.

The layer formation processes may include various deposition techniques such as chemical vapor deposition (CVD), physical vapor deposition (PVD), or atomic layer deposition (ALD). One example of a layer formed by a CVD process is a silicon oxide layer used as an insulating layer or an insulating interlayer in a semiconductor device. Another example of a layer formed by a CVD process is a silicon nitride layer used to form a mask pattern or a gate spacer. Various metal layers used for metal wiring, electrodes, and so forth, can also be formed using CVD, PVD, or ALD processes.

A titanium nitride (TiN) layer is often formed in a semiconductor device using a CVD, PVD or ALD process. The TiN layer is commonly used as a metal barrier layer to prevent metal from diffusing through various layers of the devices. For example, a TiN layer may be formed beneath a metal wiring (e.g., a copper wiring), a contact plug, or an upper electrode of a capacitor to prevent metal from diffusing into lower regions, such as the gate electrodes of a transistor, a dielectric layer of a capacitor, or a surface portion of a substrate. Various methods of forming TiN layers are disclosed, for example, in U.S. Pat. Nos. 6,436,820 and 6,555,183, and in U.S. Patent Application Publication No. 2003/0186560.

In some cases, a TiN layer is used as a barrier layer between an upper electrode and a dielectric layer of a capacitor. For example, the TiN layer can be formed on the dielectric layer, and a polysilicon layer or a metal layer serving as the upper electrode can be formed on the titanium nitride layer. In other cases, the titanium nitride layer itself can be used as the lower or upper electrode of the capacitor.

Several new processing techniques have been developed in response to the demand for semiconductor devices with increased integration density. For example, some processing techniques now use materials with a relatively high dielectric constant (high-k materials) to form gate insulating layers for transistors or high-k dielectric layers for capacitors. Other processing techniques use materials with a relatively low dielectric constant (low-k materials) to form insulating interlayers, e.g., for reducing parasitic capacitance in metal wiring connections.

Examples of high-k materials include yttrium oxide (Y₂O₃), hafnium oxide (HfO₂), zirconium oxide (ZrO₂), niobium oxide (Nb₂O₅), barium titanium oxide (BaTiO₃), and strontium titanium oxide (SrTiO₃). Where a high-k material is used as a dielectric layer for a capacitor, byproducts may be produced by reactions between the dielectric layer and lower and/or upper electrodes of the capacitor. Unfortunately, these byproducts may deteriorate the electrical characteristics of the dielectric layer. For example, where a zirconium oxide layer is formed on a TiN layer used as a lower or upper electrode, zirconium chloride (ZrCl₄) may be formed by a reaction between a zirconium precursor and chlorine residue on the TiN layer. Similarly, where a TiN layer is formed on a zirconium oxide layer, zirconium chloride may be formed by a reaction between titanium chloride (TiCl₄) and the zirconium oxide layer.

The titanium nitride layer is generally formed by a CVD process using TiCl₄ and NH₃ gases and a process temperature of about 680° C. Under these processing conditions, the CVD process tends to leave some chlorine residue on the TiN layer. The amount of chlorine residue can be reduced by increasing the process temperature. However, increasing the process temperature can negatively effect the step coverage of the titanium nitride layer. Moreover, where the process temperature is raised to reduce the chlorine content of the titanium nitride layer, thermal stress increases in underlying structures such as layers or patterns formed on the substrate.

To avoid some of the above-described problems associated with the CVD process, the titanium nitride layer is often formed with the ALD process. By forming the titanium nitride layer at a process temperature lower than about 600° C. by the ALD process, the chlorine content of the titanium nitride layer can be decreased without negatively impacting the step coverage of the titanium nitride layer. One drawback of the ALD process, however, is that it provides a relatively low manufacturing throughput compared with the CVD process.

Another alternative to the CVD process is a sequential flow deposition (SFD) process. The SFD process includes step of supplying TiCl₄ gas and NH₃ gas to form a titanium nitride layer, a preliminary purging step, a step of supplying NH₃ gas to remove chlorine atoms remaining in the titanium nitride layer, and a secondary purging step. Although the SFD process provides better manufacturing throughput than the ALD process, the throughput of the SFD process is still lower than that of the CVD process.

### SUMMARY OF THE INVENTION

Exemplary embodiments of the present invention provide various methods of manufacturing semiconductor devices. These methods are designed to provide improved manufacturing throughput relative to conventional manufacturing techniques, and the methods are also designed to prevent chemical reactions between a high-k dielectric layer and a lower or upper electrode of a capacitor.

According to one embodiment of the invention, a method of manufacturing a semiconductor device comprises forming a lower electrode on a substrate, forming a composite layer comprising a dielectric layer formed of a high-k material and a first reaction barrier layer, on the lower electrode, and forming an upper electrode on the composite layer.

In some embodiments of the present invention, the lower and upper electrodes each comprise titanium nitride, the high-k material comprises zirconium oxide, and the first reaction barrier layer comprises hafnium oxide or aluminum oxide. In addition, the upper electrode is formed using a processing temperature between about 350 and about 500° C.

### BRIEF DESCRIPTION OF THE DRAWINGS

The invention is described below in relation to several embodiments illustrated in the accompanying drawings. Throughout the drawings like reference numbers indicate like exemplary elements, components, or steps. In the drawings:

FIGS. 1 through 3 are cross-sectional views illustrating a method of manufacturing a semiconductor device in accordance with one embodiment of the present invention;

FIG. 4 is a graph illustrating a functional relationship between process temperature and respective amounts of hafnium chloride (HfCl₄) and zirconium chloride (ZrCl₄) produced by a reaction between titanium nitride and hafnium oxide, and a reaction between titanium nitride with hafnium oxide;

FIG. 5 is a graph illustrating leakage current through a zirconium oxide layer as a function of an applied voltage;

FIG. 6 is a graph illustrating leakage current through a hafnium oxide layer as a function of an applied voltage;

FIGS. 7 through 9 are cross-sectional views illustrating a method of manufacturing a semiconductor device in accordance with another embodiment of the present invention;

FIGS. 10 through 12 are cross-sectional views illustrating a method of manufacturing a semiconductor device in accordance with yet another embodiment of the present invention; and,

FIGS. 13 through 17 are cross-sectional views illustrating a method of manufacturing a semiconductor device in accordance with still another embodiment of the present invention.

### DESCRIPTION OF EXEMPLARY EMBODIMENTS

Exemplary embodiments of the invention are described below with reference to the corresponding drawings. These embodiments are presented as teaching examples. The actual scope of the invention is defined by the claims that follow.

Throughout this written description, elements that are referred to as being “on,” “over,” or “above” another element can either be directly on the other element, or intervening elements may be present. However, where an element is referred to as being “directly on” another element, there are no intervening elements present.

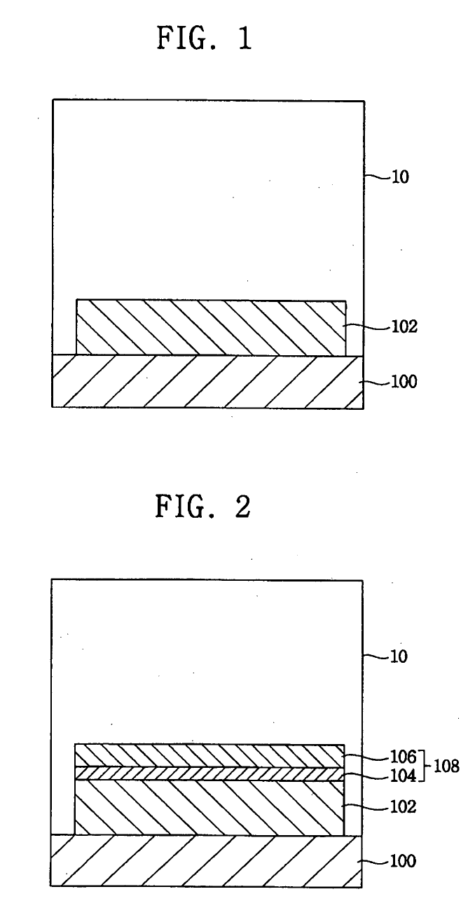

FIGS. 1 through 3 are cross-sectional views illustrating a method of manufacturing a semiconductor device in accordance with one embodiment of the present invention.

Referring to FIG. 1, a lower electrode 102 is formed on a semiconductor substrate 100 such as a silicon wafer. Lower electrode 102 comprises titanium nitride and it is formed by a TiCl₄ pulsed deposition (TPD) process. The TPD process is performed by supplying a first reactant including titanium and chlorine and a second reactant including nitrogen into a process chamber 10 to form a first titanium nitride layer (not shown) on substrate 100. The first reactant typically comprises TiCl₄ gas and the second reactant typically comprises NH₃ gas.

In the TPD process the TiCl₄ gas and the NH₃ gas are initially supplied to process chamber 10 with respective first and second flow rates. Preferably, the ratio of the second flow rate to the first flow rate is about 1. Next, the supply of TiCl₄ gas is adjusted to a third flow rate that is smaller than the first flow rate, and the supply of NH₃ gas is adjusted to a fourth flow rate that is larger than the second flow rate. As a result, a second titanium nitride layer (not shown) is formed on the first titanium nitride layer. By supplying the TiCl₄ gas and the NH₃ gas with the respective third and fourth flow rates, free chlorine atoms remaining in the first and second titanium nitride layer are substantially removed by NH₃ gas supplied while forming the second titanium nitride layer.

The ratio of the third flow rate to the first flow rate is preferably between 0.01 and 0.2, and the ratio of the fourth flow rate to the second flow rate is preferably between 10 and 20. Where the third flow rate is greater than about 20% of the first flow rate, the deposition rate of the second titanium nitride layer may increase, but the efficiency of the chlorine removal may decrease. Similarly, where the fourth flow rate is smaller than about 1000% of the second flow rate, the efficiency of the chlorine removal may decrease. Preferably, each of the first and second titanium nitride layers will take about three to twenty seconds to form. Where the time required to form the first titanium nitride layer is longer than about twenty seconds, the efficiency of the chlorine removal performed while forming the second titanium nitride layer may decrease.

In one example, the first and second flow rates are both 60 standard cubic centimeters per minute (sccm) and the third and fourth flow rates are 5 sccm and 1000 sccm, respectively.

Instead of supplying the TiCl₄ and the NH₃ with the respective third and fourth flow rates when forming the second titanium nitride layer, the TiCl₄ gas can be interrupted and the NH₃ gas can be supplied to process chamber 10 at a fifth flow rate, which is greater than the second flow rate. Under these conditions, the second titanium nitride layer will be formed by a reaction between the NH₃ gas supplied at the fifth flow rate and any TiCl₄ gas remaining in process chamber 10. In other words, any chlorine atoms remaining in the first and second titanium nitride layers will be removed by a reduction reaction with the NH₃ gas supplied at the fifth flow rate. Preferably, the fifth flow rate is substantially equal to the fourth flow rate.

In general, the processes used to form the first and second titanium nitride layers are repeated several times until lower electrode 102 has a desired thickness.

The TiCl₄ gas may be supplied to process chamber 10 by a bubbler system or a liquid delivery system (LDS) including a vaporizer. An inert gas, such as argon, nitrogen, or helium, may be used as a carrier gas for providing the TiCl₄ gas and the NH₃ gas.

Because the NH₃ gas removes the chlorine atoms from process chamber 10, there is no need to raise the temperature of process chamber 10 above 600° C. Accordingly, the temperature of process chamber 10 is generally maintained in a range from about 300 to 600° C. Preferably, the temperature of process chamber 10 is maintained at approximately 400° C. Dropping the temperature of process chamber 10 below about 300° C. will generally cause the reactivity between the first and second reactants to deteriorate. On the other hand, raising the temperature of process chamber 10 above 600° C. will tend to increase thermal stress on substrate 100.

The pressure of process chamber 10 is generally maintained between about 0.1 and 2.0 torr. Preferably, the pressure of process chamber 10 is maintained between 0.3 and 1.0 torr. Where the pressure in process chamber 10 is less than 0.1 torr, the reactivity of the first and second reactants supplied into the process chamber 10 may deteriorate. However, where the pressure in process chamber 10 is greater than 2.0 torr, it is difficult to control process conditions.

Referring to FIG. 2, a composite layer 108 including a reaction barrier layer 104 and a dielectric layer 106 is formed on the lower electrode 102. Reaction barrier layer 104 typically comprises hafnium oxide and is formed by an ALD process using a hafnium precursor and an oxidizing agent. Alternatively, the reaction barrier layer 104 could comprise aluminum oxide and be formed by an ALD process using an aluminum precursor and an oxidizing agent.

To form reaction barrier layer 104, a third reactant comprising hafnium or aluminum is deposited onto lower electrode 102. For example, a gaseous hafnium precursor or a gaseous aluminum precursor is generally supplied onto lower electrode 102. The third reactant is generally provided by a LDS or a bubbler system. The hafnium precursor may include, for example, tetrakis dimethyl amino hafnium (Hf[N(CH₃)₂]₄ or TDMAH), tetrakis ethyl methyl amino hafnium (Hf[N(C₂H₅)CH₃]₄ or TEMAH), or tetrakis diethyl amino hafnium (Hf[N(C₂H₅)₂]₄ or TDEAH). The aluminum precursor may include, for example, trimethyl aluminum (Al(CH₃)₃ or TMA), or triethyl aluminum (Al(C₂H₅)₃ or TEA). These precursors may be used alone or in a mixture.

The third reactant is generally supplied onto lower electrode 102 for about 0.5 to 3 seconds, preferably 2 seconds.

Some of the supplied third reactant is chemisorbed on lower electrode 102. The remainder of the third reactant that is not chemisorbed on lower electrode 102 is physisorbed on the chemisorbed portion or it drifts around in process chamber 10.

While the third reactant is supplied to process chamber 10, the temperature of process chamber 10 is maintained between about 150 and 500° C. Where the temperature in process chamber 10 is lower than 150° C., the reactivity of the third reactant tends to deteriorate. On the other hand, where the temperature in process chamber 10 is higher than 500° C., reaction barrier layer 104 tends to rapidly crystallize. To prevent the deterioration of the reactivity of the third reactant and also to prevent the rapid crystallization of reaction barrier layer 104, the temperature in process chamber 10 is typically maintained between 250 and 350° C. Preferably, the temperature in process chamber 10 is maintained at approximately 300° C.

Similarly, where the pressure in process chamber 10 is less than 0.1 torr, the reactivity of the third reactant tends to deteriorate, and where the pressure in process chamber 10 is greater than 3.0 torr, it is difficult to control other process conditions. Thus, the pressure in process chamber 10 is preferably maintained between 0.1 and 3.0 torr.

After the third reactant is supplied to process chamber 10, a purge gas is then supplied into process chamber 10. The purge gas preferably comprises an inert gas such as argon or nitrogen. The purge gas is generally supplied into process chamber 10 for about 0.5 to 5 seconds, preferably 2 seconds.

Portions of the third reactant that were not chemisorbed into lower electrode 102 are exhausted from process chamber 10 together the supplied purge gas.

Next, a first oxidizing agent is supplied onto the chemisorbed portions of the third reactant to form a first atomic layer (not shown) on lower electrode 102. The first atomic layer includes hafnium oxide or aluminum oxide and is formed by a reaction between the first oxidizing agent and the chemisorbed portions of the third reactant. The first oxidizing agent generally comprises a composition such as O₃, O₂, H₂O, or plasma O₂. The composition may be used alone or in a mixture. Preferably, the first oxidizing agent comprises O₃ and is supplied for about 1 to 5 seconds.

After the first oxidizing agent is supplied onto the chemisorbed portions of the third reactant, a purge gas is introduced into chamber 10. Then, any byproducts produced by the reaction between the chemisorbed first portion of the third reactant and the first oxidizing agent, as well as any remaining portion of the first oxidizing agent, are exhausted from process chamber 10 together with the purge gas. The purge gas is generally introduced into chamber 10 for about 1 to 5 seconds, preferably 3 seconds.

The third reactant and the first oxidizing agent are repeatedly supplied to process chamber 10 as described above until reaction barrier layer 104 is formed with a desired thickness. Since an aluminum oxide layer has a larger energy band gap than a hafnium oxide layer, reaction barrier layer 104 can be formed with a smaller thickness when it comprises aluminum oxide as opposed to when it comprises hafnium oxide. For example, where reaction barrier layer 104 comprises hafnium oxide, the reaction barrier layer generally has a thickness of about 1 to 50 Å. On the other hand, where reaction barrier layer 104 comprises aluminum oxide, the reaction barrier layer generally has a thickness of about 1 to 20 Å.

After reaction barrier layer 104 is formed, dielectric layer 106 is formed thereon. Dielectric layer 106 is typically formed of a material having a higher dielectric constant than reaction barrier layer 104. For example, dielectric layer preferably comprises zirconium oxide.

Dielectric layer 106 is preferably formed by supplying a fourth reactant including a zirconium precursor onto reaction barrier layer 104. While dielectric layer 106 is being formed, the temperature and pressure in process chamber 10 are preferably maintained at the same levels as when reaction barrier layer 104 is being formed.

Some of the fourth reactant is chemisorbed on reaction barrier layer 104. The remainder of the fourth reactant that is not chemisorbed on reaction barrier layer 104 is physisorbed on the chemisorbed portion or it drifts around in process chamber 10.

The zirconium precursor typically comprises a composition such as tetrakis ethyl methyl amino zirconium (Zr[N(C₂H₅)CH₃]₄ or TEMAZ), or zirconium t-butoxide (Zr(OtBu)₄). The composition can be used by itself or in a mixture. The fourth reactant is typically supplied to process chamber 10 for about 0.5 to 3 seconds, preferably 2 seconds.

After the fourth reactant is supplied onto reaction barrier layer 104, a purge gas is supplied into process chamber 10. The purge gas typically comprises an inert gas such as argon or nitrogen. The purge gas may is generally supplied into process chamber 10 for about 0.5 to about 5 seconds, preferably 2 seconds. The purge gas is then exhausted from process chamber 10 and the physisorbed and drifting portions of the fourth reactant are exhausted from process chamber 10 together with the purge gas.

A second oxidizing agent is supplied to process chamber 10 on the chemisorbed portions of the fourth reactant. As a result, a second atomic layer (not shown) including zirconium oxide is formed on reaction barrier layer 104 by a reaction between the second oxidizing agent and the chemisorbed portions of the fourth reactant. The second oxidizing agent may typically includes a composition such as O₃, O₂, H₂O, or plasma O₂, preferably O₃. The composition can be supplied alone or in a mixture. The second oxidizing agent is typically supplied to process chamber 10 for about 1 to 5 seconds, preferably 3 seconds.

After the second atomic layer is formed on reaction barrier layer 104, a purge gas is introduced into process chamber 10. The purge gas is subsequently exhausted from process chamber 10, together with any byproducts produced by the reaction between the chemisorbed portions of the fourth reactant and the second oxidizing agent, and any remaining second oxidizing agent in process chamber 10. The purge gas is generally supplied to process chamber 10 for about 1 to 5 seconds, preferably 3 seconds.

The fourth reactant and the second oxidizing agent are repeatedly supplied to process chamber 10 as described above until dielectric layer 106 is formed with a desired thickness on reaction barrier layer 104. Dielectric layer 106 is preferably formed with a thickness between 50 and 150 Å.

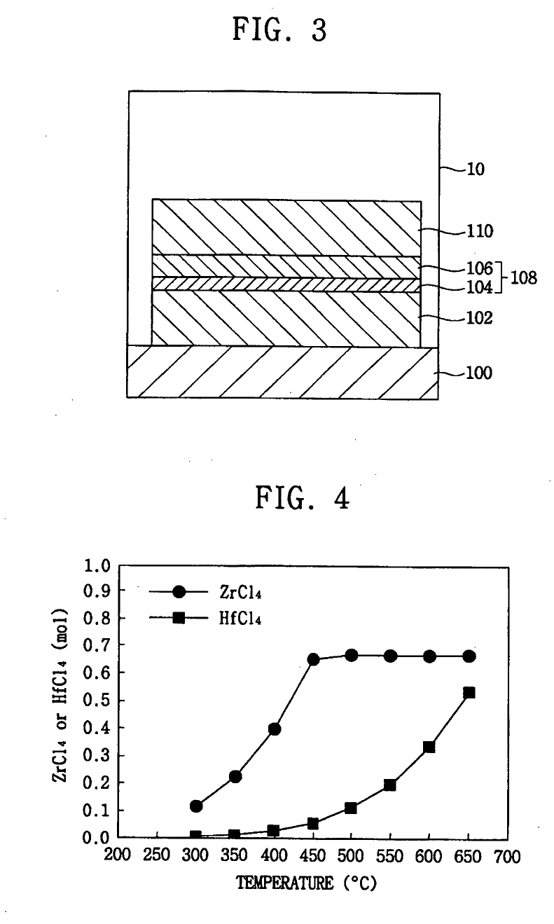

Referring to FIG. 3, an upper electrode 110 is formed on dielectric layer 106 to form a capacitor. Upper electrode 110 typically comprises titanium nitride and is formed in substantially the same way as lower electrode 102. Reaction barrier layer 104 is designed to prevent any reaction between dielectric layer 106 and lower electrode 102 during the formation of upper electrode 110.

FIG. 4 is a graph illustrating how temperature affects the amounts of hafnium chloride (HfCl₄) and zirconium chloride (ZrCl₄) that are produced by respective reactions between titanium nitride and hafnium oxide and between titanium nitride and zirconium oxide during the formation of the capacitor in FIG. 3.

Referring to FIG. 4, the amount of zirconium chloride (ZrCl₄) produced rapidly increases as temperature increases from 300 to 450° C. In contrast, the amount of hafnium chloride (HfCl₄) produced slowly increases as temperature increases between 300 and 650° C. Thus, where hafnium oxide is used to form reaction barrier layer 104, hafnium chloride (HfCl₄) may be produced by a reaction between lower electrode 102 and reaction barrier layer 104; however, dielectric layer 106 will be substantially prevented against deterioration due to the production of zirconium chloride (ZrCl₄).

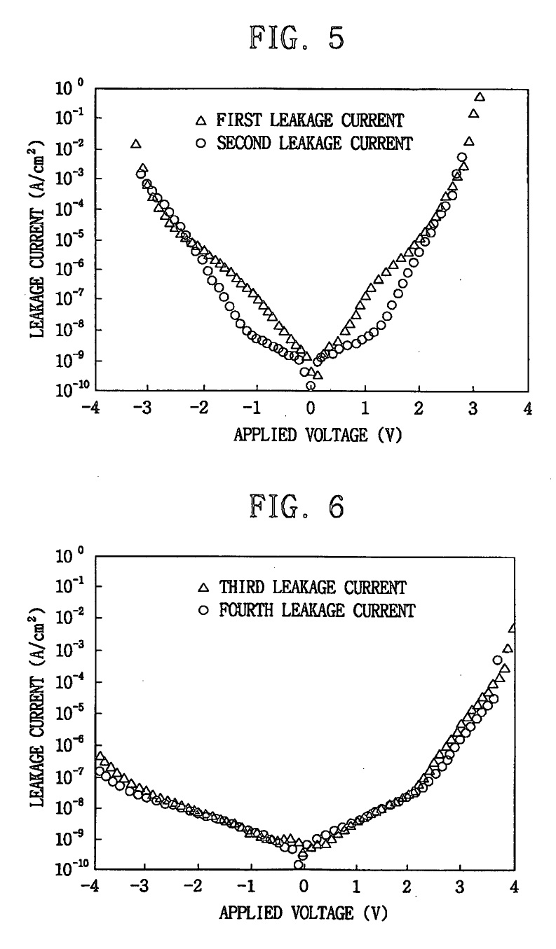

FIG. 5 is a graph illustrating the respective levels of leakage currents through two different zirconium oxide layers as a function of respective voltages applied to the zirconium oxide layers. The zirconium oxide layers are similar to the second atomic layer described in relation to FIG. 3. FIG. 6 is a graph illustrating the respective levels of leakage currents through two hafnium oxide layers as a function of voltages applied to the hafnium oxide layers. The hafnium oxide layers are similar to the first atomic layer described in relation to FIG. 3.

Referring to FIGS. 5 and 6, a first zirconium oxide layer is formed on a first lower electrode, and a first upper electrode is formed on the first zirconium oxide layer. The first lower electrode is formed at a process temperature of about 450° C. by a CVD process using TiCl₄ and NH₃ gases, and the first upper electrode is formed in substantially the same manner as the first lower electrode. The first zirconium oxide layer is formed at a process temperature of about 250° C. to a thickness of about 90 Å by an ALD process using TEMAZ and O₃.

A second zirconium oxide layer is formed on a second lower electrode, and a second upper electrode is formed on the second zirconium oxide layer. The second lower electrode is formed at a process temperature of about 150° C. by a PVD process, and the second upper electrode is formed in a substantially same manner as the second lower electrode. The second zirconium oxide layer is formed in substantially the same manner as the first zirconium oxide layer.

A first hafnium oxide layer is formed on a third lower electrode, and a third upper electrode is formed on the first hafnium oxide layer. The third lower electrode is formed at a process temperature of about 450° C. by a CVD process using TiCl₄ and NH₃ gases, and the third upper electrode is formed in substantially the same manner as the third lower electrode. The first hafnium oxide layer is formed at a process temperature of about 300° C. to a thickness of about 80 Å by an ALD process using TEMAH and O₃.

A second hafnium oxide layer is formed on a fourth lower electrode, and a fourth upper electrode is formed on the second hafnium oxide layer. The fourth lower electrode is formed at a process temperature of about 150° C. by a PVD process, and the fourth upper electrode is formed in substantially the same manner as the fourth lower electrode. The second hafnium oxide layer is formed in substantially the same manner as the first hafnium oxide layer.

In FIG. 5, a first leakage current (denoted by triangles) through the first zirconium oxide layer is generally higher than a second leakage current (denoted by circles) through the second zirconium oxide layer. In FIG. 6, a third leakage current (denoted by triangles) through the first hafnium oxide layer has similar levels compared with a fourth leakage (denoted by circles) through the second hafnium oxide layer.

Based on the results shown in FIGS. 5 and 6, relatively large quantities of zirconium chloride (ZrCl₄) are formed between the first lower electrode and the first zirconium oxide layer by the reaction of chlorine atoms remaining in the first lower electrode with the first zirconium oxide layer after forming the first upper electrode. In addition, relatively large quantities of zirconium chloride (ZrCl₄) are formed between the zirconium oxide layer and the first upper electrode by a reaction of the zirconium oxide layer with TiCl₄ gas while forming the first upper electrode. In contrast, relatively small quantities of hafnium chloride (HfCl₄) are formed between the third lower electrode and the first hafnium oxide layer and between the hafnium oxide layer and the third upper electrode when the CVD process is performed.

Based on the foregoing explanation, reaction barrier layer 104 substantially prevents lower electrode 102 from reacting with dielectric layer 106, thereby decreasing leakage current between lower and upper electrodes 102 and 110.

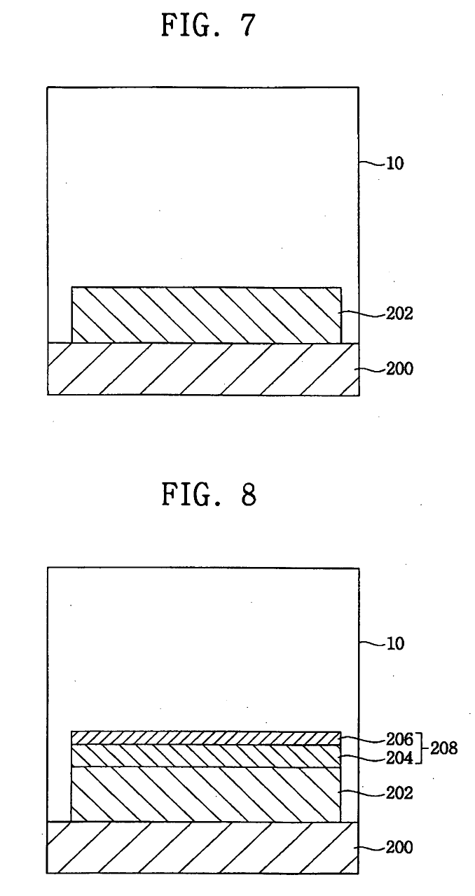

FIGS. 7 to 9 are cross-sectional views illustrating a method of manufacturing a semiconductor device in accordance with another embodiment of the present invention.

Referring to FIG. 7, a lower electrode 202 comprising titanium nitride is formed on a semiconductor substrate 200. Lower electrode 202 is preferably formed by a TPD process using TiCl₄ gas and NH₃ gas. The TPD process used to form lower electrode 202 is similar to the TPD process used to form lower electrode 102 in FIG. 3 and therefore a further description of the TPD process will be omitted to avoid redundancy.

Referring to FIG. 8, a composite layer 208 including a dielectric layer 204 and a reaction barrier layer 206 is formed on lower electrode 202. Dielectric layer 204 comprises zirconium oxide and is formed on the lower electrode 202. Reaction barrier layer 206 comprises hafnium oxide or aluminum oxide and is formed on dielectric layer 204 to prevent a reaction between dielectric layer 204 and a subsequently formed upper electrode.

Dielectric layer 204 is preferably formed by an ALD process using a zirconium precursor and oxidizing agent, and reaction barrier layer 206 is preferably formed by an ALD process using a hafnium or aluminum precursor and an oxidizing agent. The ALD processes used to form dielectric layer 204 and reaction barrier are similar to the respective processes used to form dielectric layer 106 and reaction barrier layer 104 in FIG. 3 and therefore further explanation of these processes is omitted to avoid redundancy.

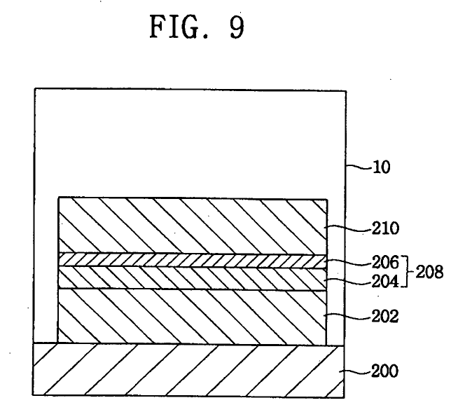

Referring to FIG. 9, an upper electrode 210 comprising titanium nitride is formed on reaction barrier layer 206. Upper electrode 210 is preferably formed by a TPD process using TiCl₄ and NH₃ gases. Preferably, upper electrode 210 is formed in substantially the same manner as lower electrode 202.

Reaction barrier layer 206 prevents chlorine atoms remaining in upper electrode 210 from reacting with dielectric layer 204, thereby preventing deterioration of the electrical characteristics of dielectric layer 204.

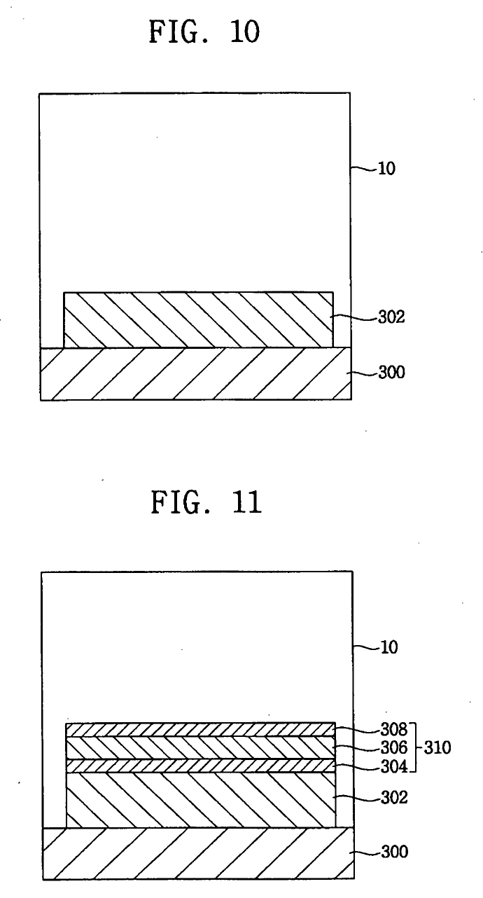

FIGS. 10 through 12 are cross-sectional views illustrating a method of manufacturing a semiconductor device in accordance with yet another embodiment of the present invention.

Referring to FIG. 10, a lower electrode 302 comprising titanium nitride is formed on a semiconductor substrate 300. Lower electrode 302 is preferably formed by a TPD process using TiCl₄ and NH₃ gases. The TPD process used to form lower electrode 302 is similar to the process used to form lower electrode 102 and therefore a further explanation thereof will be omitted to avoid redundancy.

Referring to FIG. 11, a composite layer 310 comprising a first reaction barrier layer 304, a dielectric layer 306, and a second reaction barrier layer 308, is formed on lower electrode 302. First reaction barrier layer 304 comprises hafnium oxide or aluminum oxide and is formed on the lower electrode 302 to prevent a reaction between lower electrode 302 and dielectric layer 306. Dielectric layer 306 comprises zirconium oxide and is formed on first reaction barrier layer 304. Second reaction barrier 308 comprises hafnium oxide or aluminum oxide and is formed on dielectric layer 306 to prevent a reaction between dielectric layer 306 and a subsequently formed upper electrode.

Dielectric layer 306 is preferably formed by an ALD process using a zirconium precursor and an oxidizing agent. Each of first and second reaction barrier layers 304 and 308 are preferably formed by respective ALD processes using a hafnium precursor or an aluminum precursor and an oxidizing agent.

The respective processes used to form dielectric layer 306 and first and second reaction barrier layers 304 and 308 are similar to the processes used to form dielectric layer 106 and reaction barrier layer 104. Accordingly, further explanations thereof will be omitted to avoid redundancy.

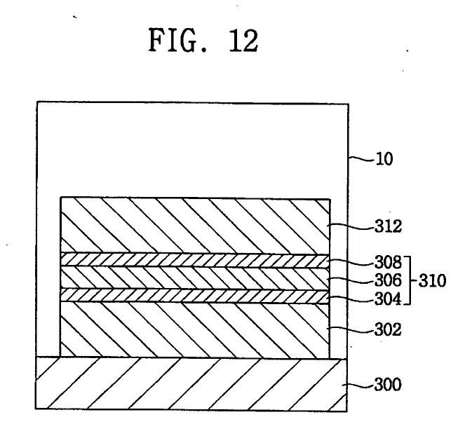

Referring to FIG. 12, an upper electrode 312 comprising titanium nitride is formed on second reaction barrier layer 310. Upper electrode 312 is preferably formed by a TPD process using TiCl₄ and NH₃ gases. Upper electrode 312 is typically formed in substantially the same manner as lower electrode 302.

By forming first reaction barrier layer 304 between lower electrode 302 and dielectric layer 206, and by forming second reaction barrier layer 308 between dielectric layer 306 and upper electrode 312, deterioration of dielectric layer 306 due to reactions with upper electrode 312 and lower electrode 302 are avoided. As a result, the electrical characteristics of dielectric layer 306 are preserved.

The inside of process chamber 10 is typically maintained at temperature of about 300 to about 600° C. during the formation of upper electrode 312. Preferably, the interior of process chamber 10 is maintained at a process temperature of about 350 to about 500° C. while forming upper electrode 312. Where the process temperature is higher than about 500° C., significant amounts of byproducts, such as hafnium chloride, may be produced by reactions between first reaction barrier layer 304 and lower electrode 302 and between second reaction barrier layer 308 and upper electrode 312. Further, the process temperature of process chamber 10 may be maintained at over approximately 350° C. in consideration of reactivity between the TiCl₄ and NH₃ gases supplied to form upper electrode 312.

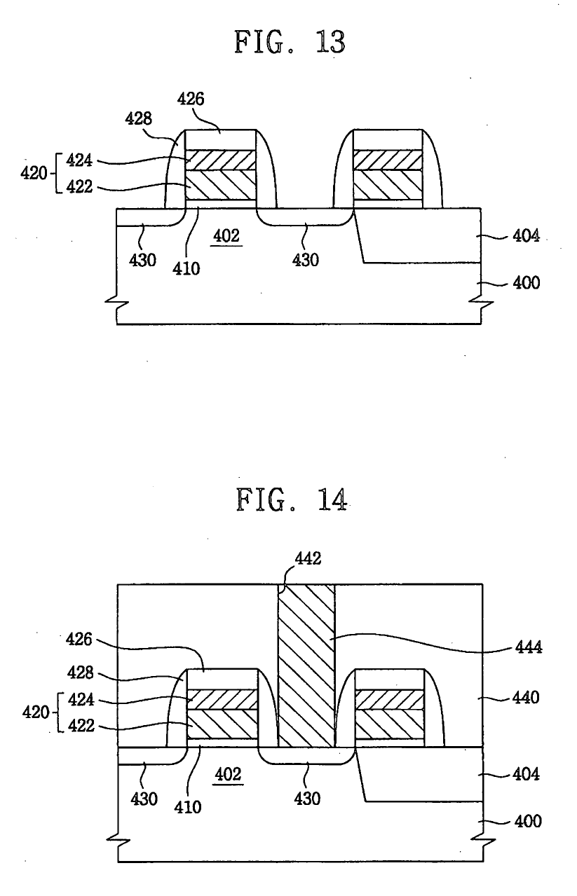

FIGS. 13 through 17 are cross-sectional views illustrating a method of manufacturing a semiconductor device in accordance with still another embodiment of the present invention.

Referring to FIG. 13, a semiconductor substrate 400 is divided into active regions 402 and field regions 404 by performing an isolation process such as a shallow trench isolation (STI) process. Then, a gate insulating layer pattern 410 and a gate electrode 420 are formed on semiconductor substrate 400. Gate electrode 420 comprises an impurity doped polysilicon pattern 422 and a metal silicide pattern 424.

A capping layer pattern 426 of silicon oxide is formed on the gate electrode 420, and a side wall spacer 428 of silicon nitride is formed on the side walls of gate electrode 420.

A transistor structure is constituted by forming impurity doped regions 430 serving as source/drain regions at surface portions of semiconductor substrate 400 adjacent to gate electrode 420. Impurity doped regions 430 are typically formed by performing an ion implantation process before and/or after forming side wall spacer 428.

Referring to FIG. 14, a first insulating layer is formed on an entire surface of semiconductor substrate 400. Then, the first insulating layer is patterned by a photolithography process to form a first insulating layer pattern 440 with a contact hole 442 exposing one of impurity doped regions 430. Then, a conductive layer filling contact hole 442 is formed on first insulating layer pattern 440. A planarization process, e.g., an etching back process or a chemical mechanical polishing process, is then performed on the conductive layer until first insulating layer pattern 440 is exposed. As a result, a contact plug 444 comprising a conductive material is formed in contact hole 442.

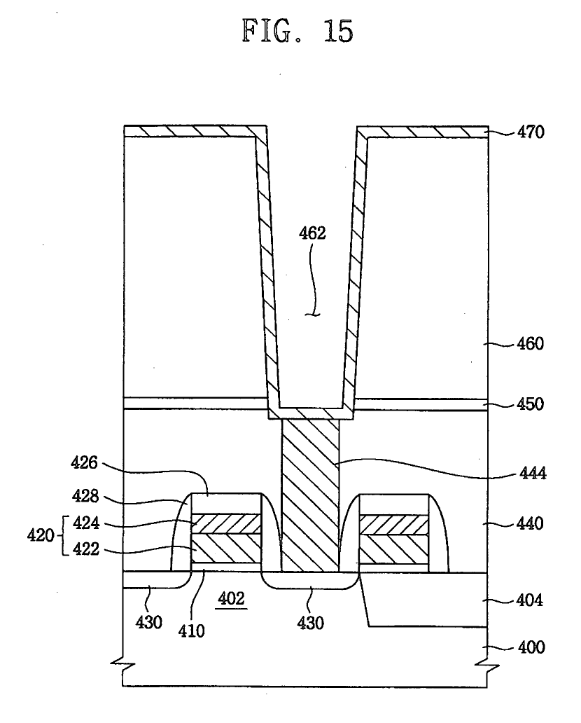

Referring to FIG. 15, an etch stop layer 450 is formed on first insulating layer pattern 440 and contact plug 444. Etch stop layer 450 is preferably formed of a material that has a high etching selectivity with respect to the first insulating layer pattern 440, such as silicon nitride and silicon oxynitride.

A second insulating layer of silicon oxide is formed on etch stop layer 450, and then patterned by a photolithography process to form a second insulating layer pattern 460 with a second contact hole 462 exposing contact plug 444.

Then, a first titanium nitride layer 470 is conformally formed on a surface of second insulating layer pattern 460 and side and bottom surfaces of second contact hole 460. First titanium nitride layer 470 is preferably formed by a TPD process using TiCl₄ and NH₃ gases. The TPD process used to form first titanium nitride layer 470 is similar to the TPD process used to form lower electrode 102, and therefore a further explanation thereof is omitted to avoid redundancy.

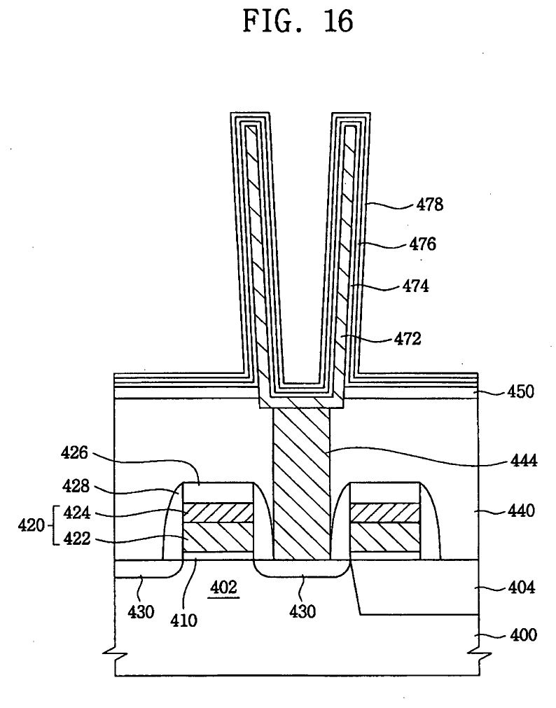

Referring to FIG. 16, a sacrificial layer filling second contact hole 462 is formed on first titanium nitride layer 470. Then, upper portions of the sacrificial layer and first titanium nitride layer 470 are removed until second insulating layer pattern 460 is exposed, leaving a lower electrode 472. Then, the sacrificial layer and second insulating layer pattern 460 are removed to expose lower electrode 472.

A first reaction barrier layer 474, a dielectric layer 476 and a second reaction barrier layer 478 are then sequentially formed on lower electrode 472 using ALD processes. Each of the first and second reaction barrier layers 474 and 478 preferably comprises hafnium oxide or aluminum oxide, and dielectric layer 476 preferably comprises zirconium oxide. The respective processes used to form first and second reaction barrier layers 474 and 478 and dielectric layer 476 are substantially the same as the processes used to form reaction barrier layer 104 and dielectric layer 106, and therefore, further explanation of these processes is omitted to avoid redundancy.

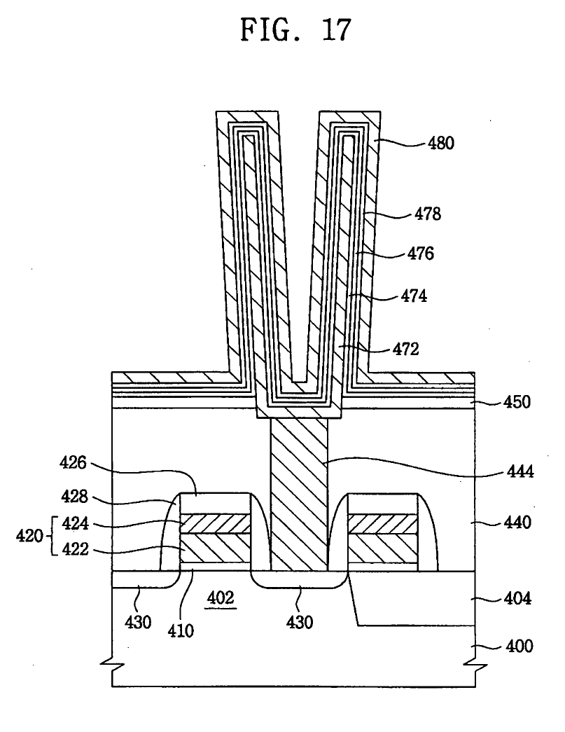

Referring to FIG. 17, a second titanium nitride layer 480 serving as an upper electrode for a cylindrical-shaped capacitor is formed on second reaction barrier layer 478. Second titanium nitride layer 480 is preferably formed by a TPD process using TiCl₄ and NH₃ gases. During the TPD process, the temperature of a process chamber where the TPD process is performed is preferably maintained between 350 and 500° C. Second titanium nitride layer 480 is preferably formed in substantially the same manner as first titanium nitride layer 470.

According to several exemplary embodiments of the invention described above, reaction barrier layers are used to prevent reactions from occurring between a dielectric layer and the upper and lower electrodes of a capacitor. In addition, a first reaction barrier layer, a dielectric layer, a second reaction barrier layer, and an upper electrode may be formed at a process temperature below 500° C. to prevent the TiCl₄ gas from reacting with the second reaction barrier layer. As a result, leakage current through the dielectric layer decreases. Still further, the capacitance of the capacitor may be increased because a high-k material layer, such as a zirconium oxide layer, is employed as the dielectric layer. Finally, the upper and lower electrodes are formed by a TPD process so that the manufacturing throughput of the capacitor is improved relative to manufacturing throughput of conventional ALD or SFD methods.

The foregoing preferred embodiments are teaching examples. Those of ordinary skill in the art will understand that various changes in form and details may be made to the exemplary embodiments without departing from the scope of the present invention as defined by the following claims.

What is claimed is:

1. A method of manufacturing a semiconductor device, the method comprising:
forming a lower electrode on a substrate;
forming a composite layer on the lower electrode, the composite layer comprising a dielectric layer formed of a high-k material, and a first reaction barrier layer; and,
forming an upper electrode on the composite layer.

2. The method of claim 1, wherein the lower and upper electrodes each comprise titanium nitride.

3. The method of claim 2, wherein the high-k material comprises zirconium oxide and the first reaction barrier layer comprises hafnium oxide or aluminum oxide.

4. The method of claim 3, wherein the dielectric layer has a thickness between 50 and 150 Å.

5. The method of claim 3, wherein the first reaction barrier layer comprises hafnium oxide and has a thickness of between about 1 and about 50 Å.

6. The method of claim 3, wherein the first reaction barrier layer comprises aluminum oxide and has a thickness between about 1 and about 20 Å.

7. The method of claim 1, wherein forming the composite layer comprises:
forming the first reaction barrier layer on the lower electrode by an atomic layer deposition (ALD) process; and,
forming the dielectric layer on the first reaction barrier layer by an ALD process.

8. The method of claim 7, wherein forming the first reaction barrier layer comprises:
supplying a reactant comprising a hafnium precursor or an aluminum precursor onto the lower electrode such that a portion of the reactant is chemisorbed on the lower electrode; and,
oxidizing the chemisorbed portion of the reactant to form hafnium oxide or aluminum oxide on the lower electrode.

9. The method of claim 8, wherein the hafnium precursor is any one selected from the group consisting of tetrakis dimethyl amino hafnium (Hf[N(CH₃)₂]₄ or TDMAH), tetrakis ethyl methyl amino hafnium (Hf[N(C₂H₅)CH₃]₄ or TEMAH), tetrakis diethyl amino hafnium (Hf[N(C₂H₅)₂]₄ or TDEAH) and a mixture thereof.

10. The method of claim 8, wherein the aluminum precursor is any one selected from the group consisting of trimethyl aluminum (Al(CH₃)₃ or TMA), triethyl aluminum (Al(C₂H₅)₃ or TEA) and a mixture thereof.

11. The method of claim 7, wherein forming the dielectric layer comprises:
supplying a reactant including zirconium precursor onto the reaction barrier layer such that a portion of the reactant is chemisorbed on the reaction barrier layer; and,
oxidizing the chemisorbed portion of the reactant to form zirconium oxide on the reaction barrier layer.

12. The method of claim 11, wherein the zirconium precursor is any one selected from the group consisting of tetrakis ethyl methyl amino zirconium (Zr[N(C₂H₅)CH₃]₄ or TEMAZ), zirconium t-butoxide (Zr(OtBu)₄) and a mixture thereof.

13. The method of claim 7, wherein forming the composite layer further comprises:
forming a second reaction barrier layer on the dielectric layer to prevent a reaction between the dielectric layer and the upper electrode.

14. The method of claim 1, wherein forming the composite layer comprises:
forming the dielectric layer on the lower electrode by an atomic layer deposition (ALD) process; and,
forming the reaction barrier layer on the dielectric layer by an ALD process.

15. The method of claim 1, wherein forming the lower electrode and forming the upper electrode each comprises:
supplying a first reactant including titanium and chlorine into a process chamber containing the substrate using a first flow rate and supplying a second reactant including nitrogen into the process chamber using a second flow rate; and,
supplying the first reactant to the process chamber using a third flow rate that is smaller than the first flow rate, and supplying the second reactant to the process chamber using a fourth flow rate that is larger than the second flow rate.

16. The method of claim 15, wherein the first reactant comprises titanium chloride (TiCl₄) and the second reactant comprises ammonia (NH₃).

17. The method of claim 15, wherein the upper electrode is formed using a processing temperature between about 350 and about 500° C.

18. The method of claim 1, wherein forming the lower electrode and forming the upper electrode each comprises:
supplying a first reactant including titanium and chlorine to a process chamber containing the substrate using a first flow rate, and supplying a second reactant including nitrogen to the process chamber using a second flow rate; and,
interrupting the supply of the first reactant and supplying the second reactant to the process chamber using a third flow rate greater than the second flow rate.

19. The method of claim 18, wherein the first reactant comprises titanium chloride (TiCl₄) and the second reactant comprises ammonia (NH₃).

20. The method of claim 18, wherein the upper electrode is formed using a processing temperature between about 350 and about 500° C.

21. The method of claim 1, further comprising:
forming a transistor comprising a gate structure located on the substrate, and impurity doped regions located in the substrate adjacent to the gate structure;
wherein the lower electrode is electrically connected to one of the impurity doped regions.

22. The method of claim 21, wherein the lower electrode is formed with a cylindrical shape.
